(19) United States
(12) Patent Application Publication
(10) Pub. No.: US 2026/0018455 A1
(43) Pub. Date: Jan. 15, 2026

(54) SEMICONDUCTOR DEVICE WITH A JUNCTION IN BACKSIDE POWER DELIVERY NETWORK

(71) Applicant: INTERNATIONAL BUSINESS MACHINES CORPORATION, ARMONK, NY (US)

(72) Inventors: HUIMEI ZHOU, Albany, NY (US); Ruilong Xie, Niskayuna, NY (US); Xiaoming Yang, Clifton Park, NY (US); LEI ZHUANG, Ridgefield, CT (US); Ravikumar Ramachandran, Pleasantville, NY (US); Mahender Kumar, Clifton Park, NY (US); Reinaldo Vega, Mahopac, NY (US)

(21) Appl. No.: 18/769,343

(22) Filed: Jul. 10, 2024

(51) Int. Cl. H01L 21/762; H01L 23/528; H01L 29/06; H01L 29/45; H01L 29/47

(52) U.S. Cl. CPC H01L 21/76224; H01L 23/5286; H10D 62/116; H10D 64/62; H10D 64/64

(57) ABSTRACT

A semiconductor device includes a shallow trench isolation (STI), a first doped region under the STI, an N-well region connected to the first doped region and the STI on a first side, a P-well region connected to the first doped region and the STI on a second side, a backside contact. A dopant concentration of the first doped region is higher than the dopant concentration of the N-well region and the dopant concentration of the P-well region.

### BACKGROUND

### Technical Field

The present disclosure generally relates to semiconductors, and more particularly, to semiconductors with a junction backside power delivery network structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a shallow trench isolation (STI), a first doped region under the STI, an N-well region connected to the first doped region and the STI on a first side, a P-well region connected to the first doped region and the STI on a second side, a backside contact. A dopant concentration of the first doped region is higher than the dopant concentration of the N-well region and the dopant concentration of the P-well region.

In one embodiment, the first doped region is doped with an N-type dopant or a P-type dopant.

In one embodiment, the first doped region is in direct contact with the backside contact to form an ohmic contact across an active region of the semiconductor device and a Schottky contact across a gate region of the semiconductor device.

In one embodiment, the Schottky contact is configured to control a turn on voltage of the semiconductor device, and the first doped region in the Ohmic contact is connected to one of the P-well or the N-well.

In one embodiment, the first doped region is surrounded by one of: a first N-well region and a second N-well region, a first P-region and a second P-region, or the first N-well region and the P-well region.

In one embodiment, the semiconductor device includes a second doped region. The first doped region or the second doped region is doped with an N-type dopant, and the first doped region or the second doped region is doped with a P-type dopant.

In one embodiment, the first doped region is located on a first plane, and the second doped region is located on a second plane.

In one embodiment, semiconductor device includes a second backside contact located on the second plane. The backside contact is located on the first plane, the first doped region is connected to the backside contact, and the second doped region is connected to the second backside contact.

In one embodiment, the semiconductor device includes a second backside contact, and a third doped region. The third doped region is a well or a region doped with an inert dopant, the third doped region isolates the first doped region and the second doped region, the first doped region is connected to the backside contact, the second doped region is connected to the second backside contact, and the first doped region, the second doped region, and the third doped region are coplanar and adjacent to each other.

In one embodiment, the first doped region and the second doped region are coplanar and directly connected to each other. The second doped region is connected to a frontside contact of the semiconductor device.

In one embodiment, the semiconductor device includes a third doped region. The third doped region is a well or a region doped with an inert dopant, the third doped region isolates the first doped region and the second doped region, the second doped region is connected to a frontside contact of the semiconductor device. The first doped region, the second doped region, and the third doped region are coplanar and adjacent to each other.

In one embodiment, the first doped region is directly connected to a frontside via of the semiconductor device to form an ohmic contact.

In one embodiment, the frontside via is located within the STI, and the frontside via is surrounded by a work function metal (WFM), an interlayer dielectric (ILD) and a substrate of the semiconductor device.

According to an embodiment, a method for fabrication of a semiconductor device includes forming a shallow trench isolation (STI), forming a first doped region under the STI, forming a backside contact, forming N-well region connected to the first doped region and the STI on a first side, forming a P-well region connected to the first doped region and the STI on a second side, forming a backside contact, doping the first doped region with a first dopant and with a first concentration, doping the N-well region with an N-type dopant and with a second concentration, and doping the P-well region with a P-type dopant and with a third concentration. The first concentration is higher than the second concentration and the third concentration.

In one embodiment, the method includes establishing a direct connect between the first doped region and the backside contact, forming an ohmic contact across an active region of the semiconductor device, and forming a Schottky contact across a gate region of the semiconductor device.

In one embodiment, providing the Schottky contact to control a turn on voltage of the semiconductor device, and establishing a direct contact between the first doped region in the ohmic contact and one of the P-well or the N-well.

In one embodiment, the first doped region is formed on a first plane, and the second doped region is formed on a second plane, and the method further includes forming a second backside contact over the second plane, forming the backside contact over the first plane, establishing a connection between the first doped region and the backside contact and establishing a connection between the second doped region and the second backside contact.

In some embodiments, the method includes forming a second backside contact and forming a third doped region. Forming the third doped region includes isolating the first doped region and the second doped region by the third doped region, establishing a connection between the first doped region and the backside contact, and establishing a connection between the second doped and the second backside contact. The third doped region is a well or a region doped with an inert dopant, the first doped region, the second doped region, and the third doped region are coplanar and adjacent to each other.

According to an embodiment, a semiconductor device includes a shallow trench isolation (STI), a doped region under the STI, a backside contact below the doped region. A dopant concentration of the doped region is higher than the dopant concentration of the doped regions connected to the doped region, and an ohmic contact is formed across an active region of the semiconductor device and a Schottky contact is formed across a gate region of the semiconductor device.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate a semiconductor device, in accordance with some embodiments.

FIGS. 2A-2B illustrate a semiconductor device with an Ohmic contact and a Schottky contact, in accordance with some embodiments.

FIGS. 3A-3B illustrate a semiconductor device with a well guard ring, in accordance with some embodiments.

FIGS. 4A-4B illustrate a semiconductor device with dual backside contacts on different planes, in accordance with some embodiments.

FIG. 4C illustrates a semiconductor device with a third doped region, in accordance with some embodiments.

FIGS. 4D-4E illustrate top views of the semiconductor device with dual backside contacts and a third doped region, respectively, in accordance with some embodiments.

FIGS. 5A-5B illustrate a semiconductor device with dual backside contacts on a same plane, in accordance with some embodiments.

FIG. 6A illustrates a semiconductor device after etching of the shallow trench isolation, in accordance with some embodiments.

FIG. 6B illustrates a top view of the semiconductor device after etching of the shallow trench isolation.

FIG. 7A illustrates a semiconductor device after the implantation of the doped region, in accordance with some embodiments.

FIG. 7B illustrates a top view of a semiconductor device after implantation of the doped region, in accordance with some embodiments.

FIG. 8A illustrates a semiconductor device after the formation of the shallow trench isolation, in accordance with some embodiments.

FIG. 8B illustrates a top view of a semiconductor device formation of the shallow trench isolation, in accordance with some embodiments.

FIG. 9A illustrates active regions of the semiconductor device after the frontside processes, in accordance with some embodiments.

FIG. 9B illustrates a top view of a semiconductor device after the frontside processes, in accordance with some embodiments.

FIG. 10A illustrates the semiconductor device after the recession of the substrate, in accordance with some embodiments.

FIG. 10B illustrates a top view of a semiconductor device after the recession of the substrate, in accordance with some embodiments.

FIG. 11A illustrates the semiconductor device after the deposition of an insulator layer, in accordance with some embodiments.

FIG. 11B illustrates a top view of a semiconductor device after the deposition of the insulating layer, in accordance with some embodiments.

FIG. 12A illustrates the active regions of the semiconductor device after the patterning of the lower via, in accordance with some embodiments.

FIG. 12B illustrates a top view of a semiconductor device after the patterning of the lower via, in accordance with some embodiments.

FIG. 13A illustrates the gate regions of the semiconductor device after the patterning of the backside contact, in accordance with some embodiments.

FIG. 13B illustrates a top view of a semiconductor device after the patterning of the backside contact, in accordance with some embodiments.

FIG. 14A illustrates the active regions of the semiconductor device after the formation of the lower via, in accordance with some embodiments.

FIG. 14B illustrates the gate regions of the semiconductor device after the formation of the backside contact, in accordance with some embodiments.

FIG. 15 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

According to an embodiment, a semiconductor device includes a shallow trench isolation (STI), a first doped region under the STI, an N-well region connected to the first doped region and the STI on a first side, a P-well region connected to the first doped region and the STI on a second side, a backside contact. A dopant concentration of the first doped region is higher than the dopant concentration of the N-well region and the dopant concentration of the P-well region. Unlike conventional semiconductors, the semiconductor device does not require substrate and substrate contact to achieve the backside power deliver network process.

In one embodiment, the first doped region is doped with an N-type dopant or a P-type dopant. Any of the N-dopant and the P-dopant can be used to dope the first doped region with.

In one embodiment, the first doped region is in direct contact with the backside contact to form an ohmic contact across an active region of the semiconductor device and a Schottky contact across a gate region of the semiconductor device. The semiconductor device can offer an ohmic contact on one plane and a Schottky contact on another plane.

In one embodiment, the Schottky contact is configured to control a turn on voltage of the semiconductor device, and the first doped region in the ohmic contact is connected to one of the P-well or the N-well. The contacts can be used to control the operation of the semiconductor device.

In one embodiment, the first doped region is surrounded by one of: a first N-well region and a second N-well region, a first P-region and a second P-region, and the first N-well region and the P-well region. Thus, the first doped region can be surrounded with both N-type well and P-type well.

In one embodiment, the semiconductor device includes a second doped region. The first doped region or the second doped region is doped with an N-type dopant, and the first doped region or the second doped region is doped with a P-type dopant. Thus, the semiconductor device can operate with dual backside contact.

In one embodiment, the first doped region and the second doped region are coplanar and directly connected to each other, and the second doped region is connected to a frontside contact of the semiconductor device. This enables utilizing two doped regions on the same plane.

In one embodiment, the semiconductor device includes a third doped region. The third doped region is a well or a region doped with an inert dopant, the third doped region isolates the first doped region and the second doped region, the second doped region is connected to a frontside contact of the semiconductor device, and the first doped region, the second doped region, and the third doped region are coplanar and adjacent to each other. Thus, all the doped regions are located on the same plane.

In one embodiment, the first doped region is directly connected to a frontside via of the semiconductor device to form an ohmic contact. This could form an ohmic contact with a silicon on insulator (SOI)

In one embodiment, the frontside via is located within the STI, and the frontside via is surrounded by a work function metal (WFM), an interlayer dielectric (ILD) and a substrate of the semiconductor device. Thus, the frontside contact and the backside contact can be completely separated, and the contact-to-contact issue is eliminated.

According to an embodiment, a method for fabrication of a semiconductor device includes forming a shallow trench isolation (STI), forming a first doped region under the STI, forming a backside contact, forming N-well region connected to the first doped region and the STI on a first side, forming a P-well region connected to the first doped region and the STI on a second side, forming a backside contact, doping the first doped region with a first dopant and with a first concentration, doping the N-well region with an N-type dopant and with a second concentration, and doping the P-well region with a P-type dopant and with a third concentration. The first concentration is higher than the second concentration and the third concentration. Unlike conventional semiconductors, the semiconductor device does not require substrate and substrate contact to achieve the backside power deliver network process.

In one embodiment, the method includes surrounding the first doped region by one of: a first N-well region and a second N-well region, a first P-well region and a second P-well region, and the first N-well region and the P-well region. Thus, the first doped region can be surrounded by different well regions.

In one embodiment, the method includes establishing a direct connect between the first doped region and the backside contact, forming an ohmic contact across an active region of the semiconductor device, and forming a Schottky contact across a gate region of the semiconductor device. The semiconductor device can offer an ohmic contact on one plane and a Schottky contact on another plane.

In one embodiment, providing the Schottky contact to control a turn on voltage of the semiconductor device, and establishing a direct contact between the first doped region in the Ohmic contact and one of the P-well or the N-well. Any of the N-dopant and the P-dopant can be used to dope the first doped region with.

In one embodiment, the first doped region is formed on a first plane and the second doped region is formed on a second plane and the method includes forming a second backside contact over the second plane, forming the backside contact over the first plane. establishing a connection between the first doped region and the backside contact, and establishing a connection between the second doped region and the second backside contact. Thus, the semiconductor device can be formed utilizing dual backside contact and two doped regions in different planes.

In one embodiment, the method includes forming a second backside contact, and forming a third doped region. Forming the third doped region includes isolating the first doped region and the second doped region by the third doped region, establishing a connection between the first doped region and the backside contact, and establishing a connection between the second doped and the second backside contact. The third doped region is a well or a region doped with an inert dopant, the first doped region, the second doped region, and the third doped region are coplanar and adjacent to each other. Thus, the dual backside contacts can be formed on the same plane by utilizing an inert doped region to isolate the doped regions.

According to an embodiment, a semiconductor device includes a shallow trench isolation (STI), a doped region under the STI, a backside contact below the doped region. A dopant concentration of the doped region is higher than the dopant concentration of the doped regions connected to the doped region, and an ohmic contact is formed across an active region of the semiconductor device and a Schottky contact is formed across a gate region of the semiconductor device. Unlike conventional semiconductors, the semiconductor device does not require substrate and substrate contact to achieve the backside power deliver network process.

Passive devices typically use a substrate and a substrate contact to achieve effective integration in a backside power delivery network process. The substrate provides the foundational layer on which the passive devices are built, while the substrate contact ensures a reliable electrical connection to the backside power delivery network. This configuration can help in maintaining the electrical performance and stability of the passive devices within the integrated circuit. In such conventional designs, passive devices such as resistors, capacitors, and inductors are often formed on the silicon substrate, with their electrical contacts extending through the substrate to connect with the backside power delivery network. This approach ensures that the passive devices receive the necessary power and grounding, allowing them to function correctly within the overall circuit design. However, this traditional method can pose challenges in terms of space utilization and isolation within the densely packed semiconductor device.

In view of the above considerations, disclosed is a semiconductor device with a junction backside power delivery network. The disclosed semiconductor device includes passive devices that utilize the region under the shallow trench isolation (STI). By placing passive devices under the STI region several significant advantages can be achieved. First, the disclosed semiconductor device allows for better utilization of the available substrate area, freeing up space on the active regions of the wafer for additional components and interconnects. This efficient use of space is particularly beneficial as semiconductor devices continue to scale down in size and increase in complexity.

Second, by forming passive devices under the STI region, the disclosed semiconductor device can offer improved electrical isolation. Further, the STI structures, filled with insulating materials such as silicon dioxide, can provide isolation properties that can help reduce parasitic capacitance and minimize noise coupling between adjacent devices. This enhanced isolation can help in maintaining the performance and integrity of passive devices, especially in high-frequency and analog applications where signal purity is paramount.

Even further, the disclosed semiconductor device can simplify the overall fabrication process. By integrating passive devices within the STI regions, the number of additional processing steps required to create separate isolation structures is reduced, which can lead to potential cost savings and increased manufacturing efficiency. The streamlined process can also enhance the yield and reliability of the disclosed semiconductor devices by minimizing the risk of defects associated with complex multi-step fabrication procedures.

Accordingly, the teachings herein provide methods and systems of semiconductor device formation with a junction backside power delivery network. The techniques described herein may be implemented in a number of ways. Example implementations are provided below with reference to the following figures.

Example Semiconductor Device with A Junction Backside Power Deliver Network Structure

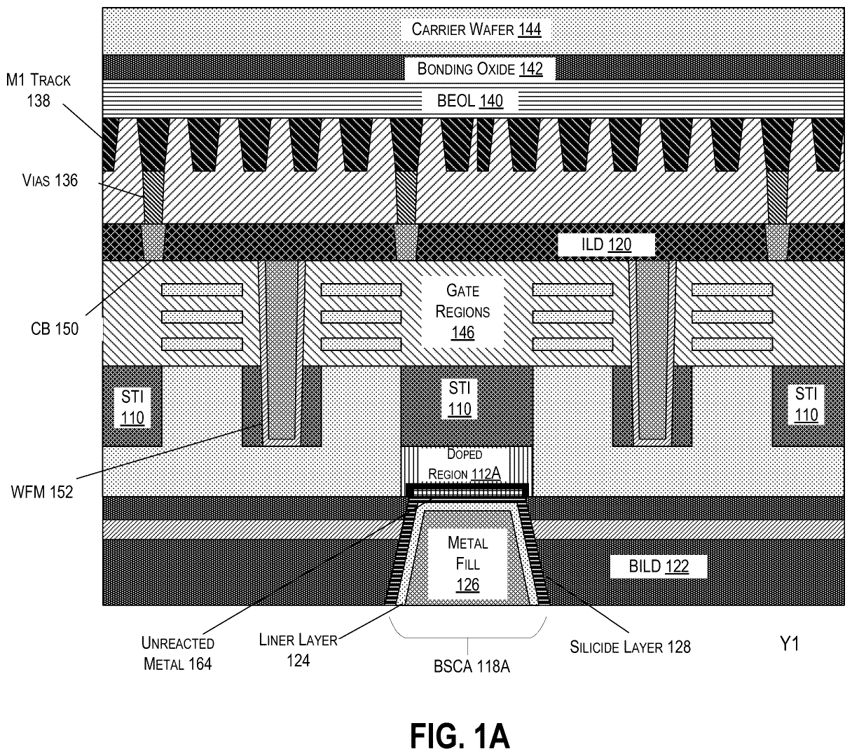

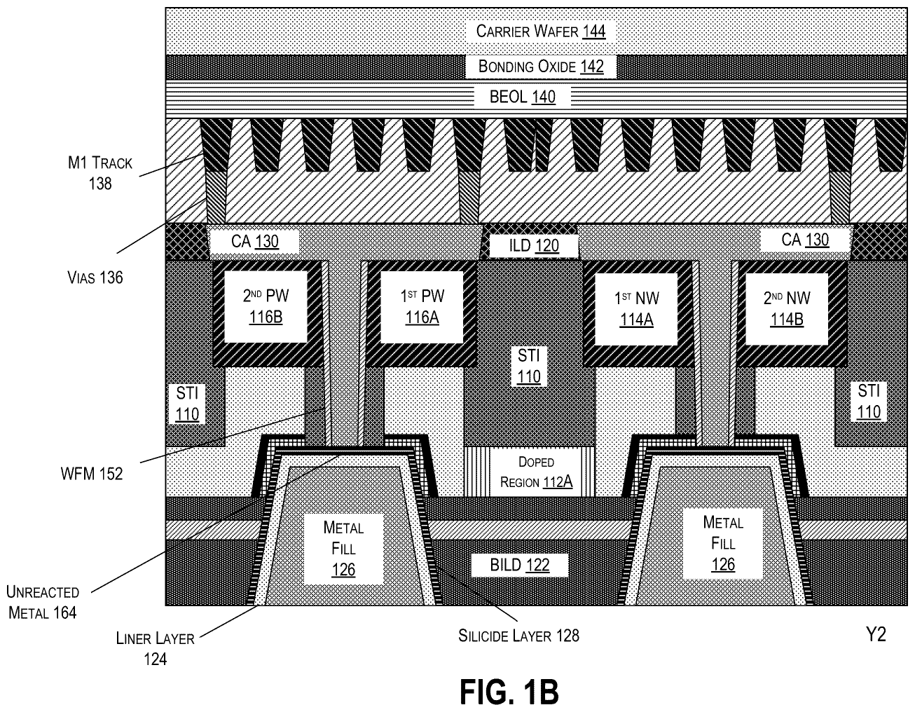

Reference now is made to FIGS. 1A-1B, which are simplified cross-section views of a semiconductor device, consistent with an illustrative embodiment. In various embodiments, the semiconductor device can be shown across active regions 100A, Y1, and across gate regions, Y2, 100B. FIG. 1C illustrates a top view of the semiconductor device depicting the Y1 cross section and the Y2 cross sections.

The semiconductor device includes a shallow trench isolation, STI 110, a first doped region 112A, a first N-well region 114A, a second N-well region 114B, a first P-well region 116A, a second P-well region 116B, a first backside contact, BSCA 118A, an interlayer dielectric, ILD 120, a bottom ILD, BILD 122, a liner layer 124, a metal fill 126, a silicide layer 128, frontside contacts, CA 130, P-type doped regions 132, N-type doped regions 134, vias 136, metal lines, M1 track 138, back end of line, BEOL 140, a bonding oxide 142, a carrier wafer 144, gate regions 146, gate contacts, CB 150, and a work metal function, WFM 152.

The STI 110 can electrically isolate different components by filling the trenches with an insulating material, such as silicon dioxide. The STI 110 can prevent electrical interference and crosstalk between adjacent devices, ensuring that each component operates independently without affecting its neighbors.

The first doped region 112A can be located below the STI 110 and be doped with an N-type dopant or a P-type dopant. The doping process can define the electrical properties of the first doped region 112A such as the conductivity and behavior under different voltage conditions. The choice between N-type and P-type doping depends on the specific requirements of the device and the desired electrical characteristics.

In some embodiments, the first doped region 112A can be in direct contact with the BSCA 118A in the gate regions 100B of the semiconductor device, and between the first N-well region 114A and the first P-well region 116A in the active regions 100A of the semiconductor device. Such configurations can allow for the formation of an ohmic contact across the active regions 100A of the semiconductor device, ensuring low-resistance electrical connections. Simultaneously, a Schottky contact can be formed across the gate regions 100B of the semiconductor device. The Schottky contact, characterized by its metal-semiconductor junction, can control the flow of current and manage the turn-on voltage of the semiconductor device.

Typically, the Schottky contact is the metal-semiconductor junction that can form a rectifying, non-ohmic contact. When a metal with a specific work function, i.e., WFM 152, interfaces with a semiconductor material, a Schottky barrier is created. The Schottky barrier can determine the electronic behavior of the junction, allowing current to flow more easily in one direction than the other, similar to a diode. This rectifying behavior is due to the potential barrier at the metal-semiconductor interface, which prevents significant current flow in the reverse direction. The Schottky contact can have a lower turn-on voltage compared to the p-n junction diodes. Additionally, in some embodiments, the Schottky contact can exhibit fast switching speeds due to the absence of minority carrier injection.

The ohmic contact, on the other hand, can be a metal-semiconductor junction that forms a non-rectifying contact which can allow current to flow equally well in both directions with minimal resistance, and to provide a low-resistance path for current to enter or exit the semiconductor device. Such a low-resistance path can be achieved by ensuring that the barrier for charge carriers, i.e., electrons or holes, is minimal or nonexistent. The ohmic contact can exhibit a linear current-voltage relationship, meaning the current through the contact can be directly proportional to the applied voltage, indicative of low resistance and efficient charge carrier injection or extraction. The ohmic contact can be formed by heavily doping the semiconductor region near the contact, reducing the barrier height and allowing for efficient charge carrier flow. In some embodiments, the Schottky contact can control a turn on voltage of the semiconductor device, and the first doped region 112A in the ohmic contact can be connected to one of the first P-well region 116A or the first N-well region 114A.

An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). In its natural state, the p-n junction allows current to flow more easily in one direction than in the opposite. When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

In some embodiments, the first N-well region 114A can be connected to the first doped region 112A and the STI 110 on one side, while the first P-well region 116A can be connected to the first doped region 112A and the STI 110 on the other side. In some embodiments, the first doped region 112A can be surrounded by different well regions.

The BSCA 118A can be a region on the backside of the semiconductor device where electrical connections are made. By establishing the electrical contacts, the BSCA 118A can ensure the proper functioning of the semiconductor device and facilitates electrical signal transmission. The BSCA 118A can serve as a thermal interface between the semiconductor device and a heat sink or other cooling mechanisms. By establishing direct contact with the substrate, the BSCA 118A can conduct the heat away from the semiconductor device, and contribute to improved thermal dissipation. In some embodiments, the BSCA 118A can help mitigate parasitic effects, such as substrate coupling or substrate noise, from the semiconductor device. In further embodiments, the BSCA 118A can allow for increased integration density in the semiconductor device.

The ILD 120 can be a layer of insulating material to electrically isolate and provide mechanical support between different layers of conducting and active components. The ILD 120 can enable efficient signal transmission, reduce crosstalk, and ensure the proper functioning of semiconductor device. In an embodiment, the ILD 120 can electrically isolate adjacent conducting layers or active components. By providing insulation between different layers, the ILD 120 can prevent electrical shorts, reduce (e.g., minimize) leakage current, and ensure that signals are directed only along the desired pathways. In some embodiments, the ILD 120 can help reduce parasitic capacitance between adjacent metal interconnects or active devices and provide mechanical support to the passive device's structure.

In several embodiments, the BILD 122 can provide structural support to the semiconductor device by maintaining the mechanical integrity and stability of the semiconductor device. The BILD 122 can further help prevent the warping, bending, or cracking of the substrate, particularly during the manufacturing process or subsequent handling. The BILD 122 can ensure that the semiconductor device remains mechanically robust and maintains its dimensional stability.

In an embodiment, the BILD 122 can also serve as a planarization layer in the semiconductor device fabrication process. As various layers are deposited and patterned on the front side of the semiconductor device, irregularities or topographic variations may arise. The BILD 122 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 122 can contribute to improved overall semiconductor device performance. In several embodiments, BILD 122 can facilitate wafer-level testing of the semiconductor device. By providing electrical isolation between the active regions and the backside contact, individual passive device or elements on the semiconductor device can be electrically accessed and tested without interference from neighboring devices or components. This enables efficient and accurate wafer-level testing, ensuring quality control during semiconductor manufacturing.

In some embodiments, the first doped region 112A in the gate regions 100B can include an epitaxial layer 160, such as silicon-germanium (SiGe), which can enhance the performance characteristics of the semiconductor device. The epitaxial layer 160 can be a layer of crystalline semiconductor material that is grown on a substrate crystal in such a way to maintain the same crystallographic orientation. In some embodiments, the epitaxial layer 160 can be made of SiGe to provide improved electron mobility compared to pure silicon.

Additionally, the semiconductor device can include a silicide layer 128, which is below the first doped region 112a and directly in contract with the first doped region 112A, to facilitate the ohmic contact formation. The silicide layer 128, which can be a titanium silicide (TiSi₂) layer, a nickel silicide (NiSi) layer, or a cobalt silicide (CoSi₂) layer, is a material that forms at the interface between silicon and metals and provides the ohmic contact.

The process of forming the silicide layer 128 can involve metal deposition followed by an annealing step. In such a process, a thin layer of metal, e.g., 2 to 4 nanometers thick, is deposited onto the silicon surface using methods such as chemical vapor deposition (CVD). The metal layer is then subjected to a low temperature anneal or a laser anneal (nLA), which causes the metal to react with the silicon, forming a stable silicide compound.

The unreacted metal 164 can be a metal layer that does not participate in the silicide formation and remains on the surface after the annealing process. In some embodiments, the unreacted metal 164 and the metal fill 126 can be the same material. The liner layer 124, which can be used to prevent diffusion and improve adhesion between different layers, is not necessary if the same metal is used as the metal fill 126 and the unreacted metal 164. The liner layer 124 can include titanium nitride (TiN) with a thickness of about 2 nanometers to about 3 nanometers.

The CA 130 located over the P-type doped regions 132 and the N-type doped regions 134, can establish connections between the P-type doped regions 132 and the N-type doped regions 134 and the BEOL 140 through the vias 136 and the M1 track 138. The CA 130 can ensure efficient electrical routing and connectivity within the semiconductor device. The fabrication of the CA 130 can involve lithography and etching processes to define the contact area. The CA 130 can be made using conductive materials such as copper (Cu) or tungsten (W).

The BEOL 140 can include metal interconnects and other structures on the upper layers of the semiconductor device to form a network of connections that link various components of the semiconductor device.

The bonding oxide 142 can be a silicon dioxide (SiO₂) layer used to provide adhesion between the semiconductor device and the carrier wafer 144. The bonding oxide 142 can be created through oxidation processes such as thermal oxidation or CVD, resulting in a thin, uniform layer of silicon dioxide on the surface of the semiconductor device to ensure that the bonded wafers maintain their structural integrity and electrical isolation.

The carrier wafer 144 can be a temporary support substrate used during various stages of semiconductor fabrication, especially when dealing with thin or fragile wafers to provide mechanical stability and facilitate the handling of delicate wafers through different processing steps, such as thinning, bonding, and dicing. The carrier wafer 144 can be made of a robust material such as silicon, which matches the thermal and mechanical properties of the active wafer to avoid stress and deformation during processing. The carrier wafer 144 can be bonded to the semiconductor device using an adhesive layer, i.e., the bonding oxide 142, and can be removed once the necessary fabrication steps are completed, leaving the processed semiconductor wafer ready for further integration or packaging.

The gate regions 146 serve as control elements that regulate the flow of current through the semiconductor device. The gate regions 146 can be composed of a conductive material. The gate regions 146 can control the flow of electric current across the channel region. In addition to acting as a switch, modulating the gate voltage can enable the gate regions 146 to control the current flowing through the channel region, resulting in amplified output signals.

In an embodiment, the gate regions 146 can enable the implementation of Boolean active operations, such as AND, OR, and NOT, by controlling the flow of current based on the input voltages. In some embodiments, the gate regions 146, along with other active device components, can facilitate the miniaturization and integration of electronic circuits. The ability to control the channel region's conductivity through the gate voltage allows for compact and highly efficient circuit designs.

The CB 150 serves as the electrical connections to the gate regions 146, allowing control over the flow of current between the gate channels. The CB 150 can be formed on top of the gate channels, and can be made of tungsten (W), aluminum (Al), or polysilicon.

The WFM 152 can be a metal to form contacts or gates, selected based on its work function, which is the energy required to move an electron from the metal surface into the vacuum. The work function of a metal can influences the barrier height formed at the metal-semiconductor interface, affecting the type of contact, e.g., Schottky or ohmic, and the electrical characteristics of the semiconductor device.

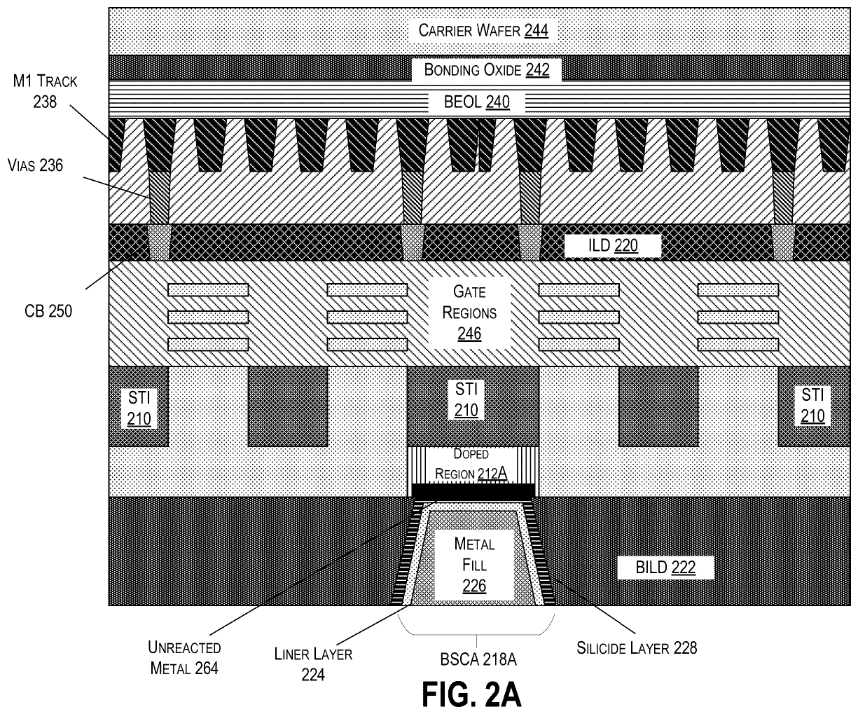

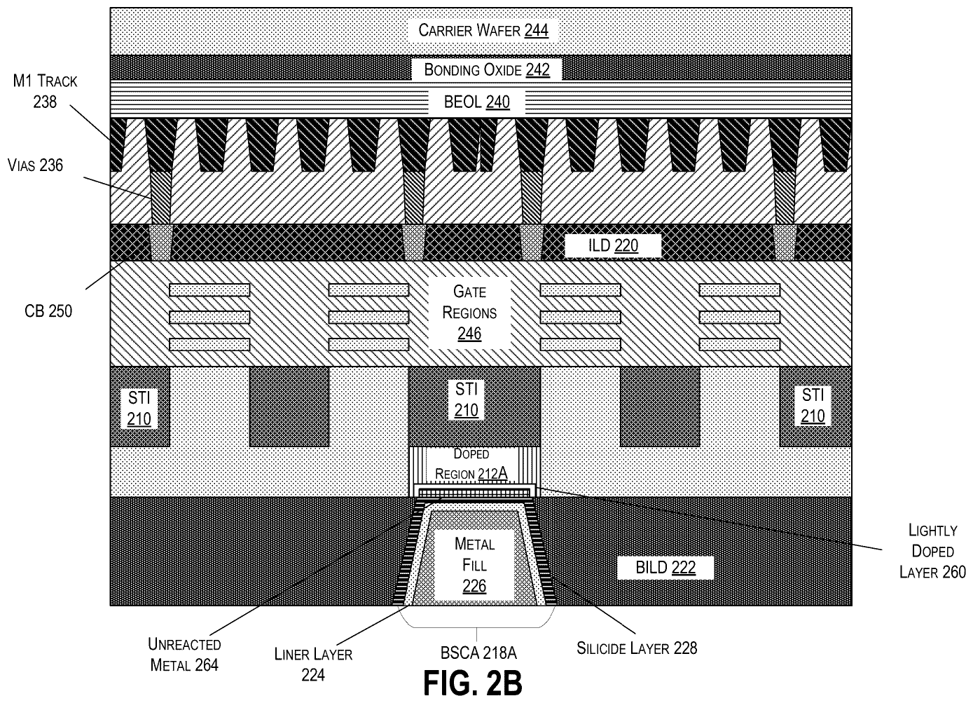

Reference is now made to FIGS. 2A-2B, in which the gate regions of a semiconductor device with an ohmic contact and a Schottky contacts are illustrated, according to some embodiments. Referring to FIG. 2A now, the gate regions of a semiconductor device with the ohmic contact is shown. In some embodiments, the first doped region 212A can be in direct contact with the BSCA 218A to form the ohmic contact across the gate regions 200A of the semiconductor device. This ohmic contact can ensure low-resistance electrical conduction, and allow efficient current flow across the gate channels. The presence of an ohmic contact can help to minimize voltage drops and power losses, which can maintain the overall performance and reliability of the semiconductor device.

The first doped region 212A, which forms the ohmic contact, can be connected to either the first N-well region 214A, or the first P-well region 216A. This connection can ensure that the electrical characteristics of the ohmic contact are aligned with the doping type of the well region, thereby facilitating efficient current flow and maintaining the integrity of the electrical connections. The choice of connecting to either the P-well or the N-well can further allow for flexibility in device design and enable the optimization of electrical performance based on the application requirements.

Referring to FIG. 2B, a Schottky contact in the gate regions of the semiconductor device is shown, according to some embodiments. In contrast to the ohmic contacts shown in FIG. 2A, the first doped region 212A can form a Schottky contact, which is characterized by its rectifying properties can control the electrical characteristics of the gate region and control the turn-on voltage of the semiconductor device. In some embodiments, the Schottky contact can adjust the turn-on voltage by tuning the work function of the metal used in the Schottky contact to meet the specific requirements of the semiconductor device. Such a control can ensure that the semiconductor device operates efficiently and responds correctly to applied voltages. The Schottky contact can be used to achieve specific electrical characteristics, such as a target Schottky barrier height and a desired turn-on voltage for the semiconductor device. The metallic compound used to form the Schottky contact can be a silicide, such as cobalt silicide (CoSi) or titanium silicide (TiSi), which can be used due to their favorable electrical properties and compatibility with silicon-based processes. Alternatively, other metals or metallic compounds, such as titanium nitride (TiN), aluminum (Al), or tungsten (W), can also be utilized to form the Schottky contact, depending on the specific requirements of the device. The Schottky contact can include a lightly doped layer 260 between the first doped region 212A and the unreacted metal 264.

In addition to the Schottky contact, the semiconductor device can incorporate a doped layer 210 to optimize its performance. The doped layer 210 can be a lightly doped layer. The lightly a doped layer can help to control the electric field distribution within the semiconductor device, improving its breakdown voltage and reducing leakage currents. The anti-doped layer, on the other hand, is doped with impurities of the opposite type to the main doping, creating a junction that can enhance the device's electrical isolation and reduce parasitic capacitance.

It should be noted that, in the ohmic contact shown in FIG. 2A and the Schottky contact shown in FIG. 2B, the first doped region 212A can be surrounded by different well regions to ensure proper isolation and functionality. For example, in some embodiments, the first doped region 212A can be enclosed by the first N-well region 214A and the second N-well region 214B, providing effective isolation for n-type doping. Alternatively, the first doped region 212A can be surrounded by the first P-well region 216A and the second P-well region 216B, ensuring isolation for p-type doping. In some embodiments, the first doped region 212A can be bordered by the first N-well region 214A and the first P-well region 216A, creating a balanced environment that leverages both n-type and p-type characteristics for optimal device performance. The specific arrangement of these well regions can facilitate achieving the desired electrical isolation, minimizing crosstalk, and enhancing the overall robustness of the semiconductor device.

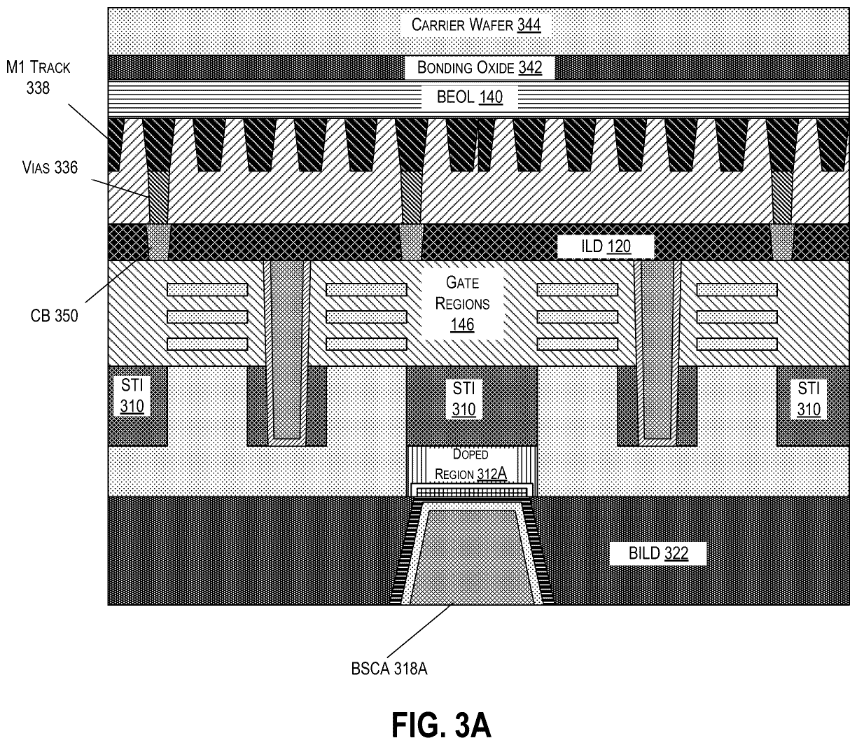

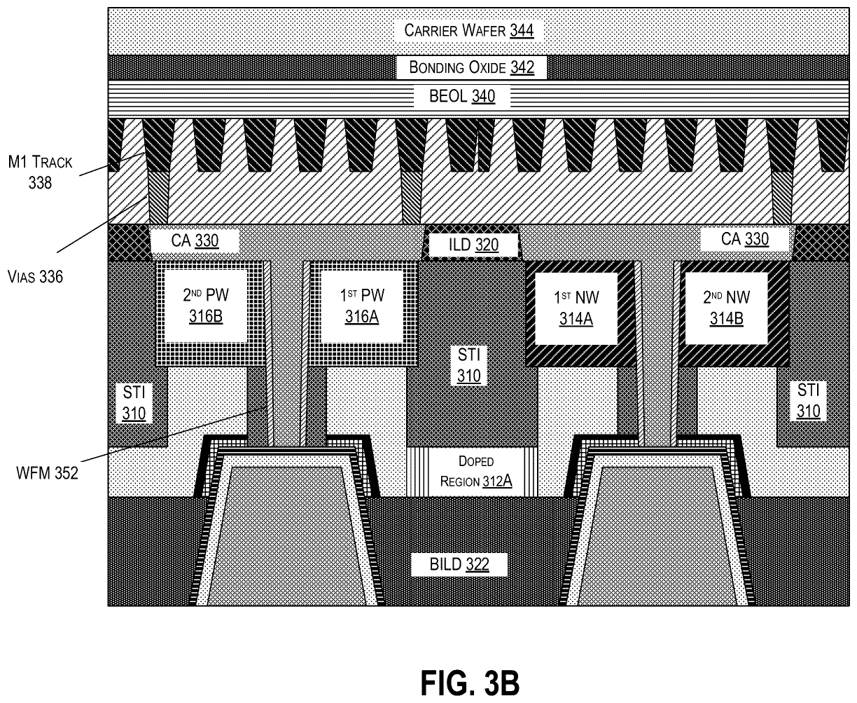

Reference is now made to FIGS. 3A-3B, in which the gate regions, as shown in FIG. 3A and active regions, as shown in FIG. 3B, of a semiconductor device with a well guard ring, according to some embodiments. In some embodiments, the first doped region 312A can be surrounded by the first N-well region 314A and the second N-well region 314B. In some embodiments, the first doped region 312A can be surrounded by the first P-well region 316A and the second P-well region 316B. Alternatively, in some embodiments, the first doped region 312A can be surrounded by the first N-well region 314A and the first P-well region 316A. Although the first doped region 312A, the first N-well region 314A and the first P-well region 316A are all doped with N-type or P-type dopants, the first doped region 312A can have a higher dopant concentration than the first N-well region 314A and the first P-well region 316A.

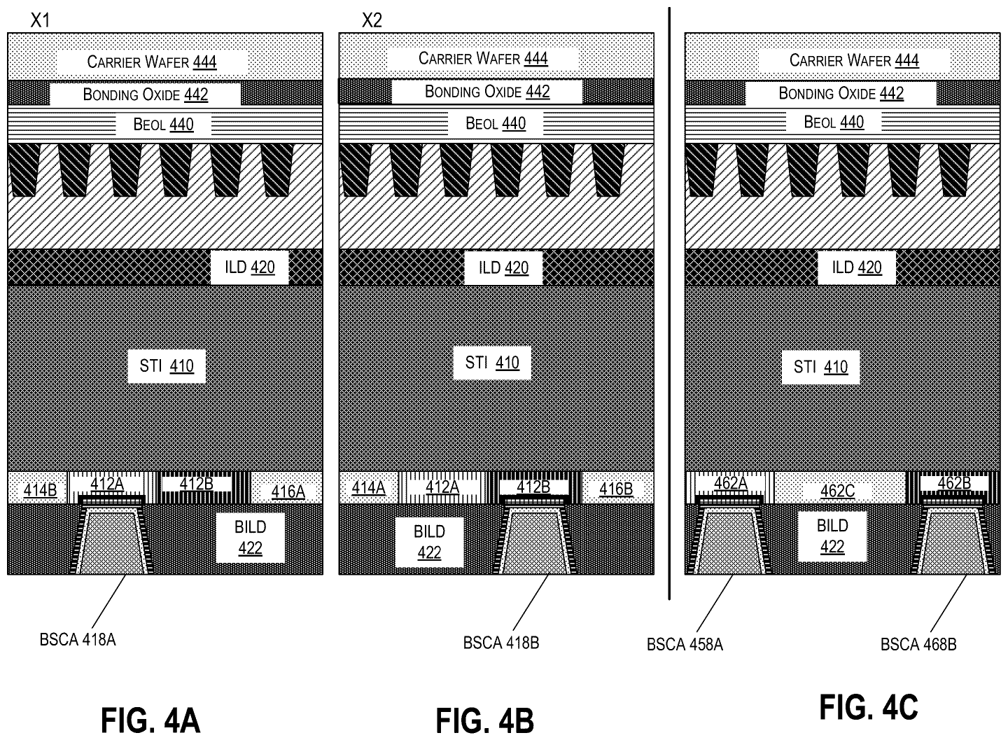

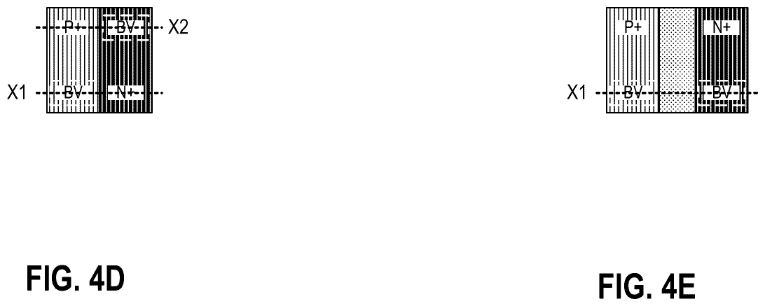

Reference is now made to FIGS. 4A-4E, in which a semiconductor device with dual backside contacts is illustrated, according to some embodiments. As illustrated in FIGS. 4A-4B, in some embodiments, the semiconductor device includes STI 410, a first doped region 412A, a second doped region 412B, a first N-well region 414A, a second N-well region 414B, a first P-well region 416A, a second P-well region 416B, a first backside contact, BSCA 418A, a second backside contact, BSCA 418B, an interlayer dielectric, ILD 420, a bottom ILD, BILD 422, back end of line, BEOL 440, a bonding oxide 442, and a carrier wafer 444.

In some embodiments, one of the first doped region 412A or the second doped region 412B is doped with an N-type dopant, which introduces extra electrons into the semiconductor material, enhancing its conductivity. Conversely, the other doped region (either the first doped region 412A or the second doped region 412B) is doped with a P-type dopant, which introduces holes, or positive charge carriers, into the semiconductor device. This complementary doping of the first doped region 412A and the second doped region 412B can ensure that one doped region has an excess of electrons (N-type) and the other has an excess of holes (P-type), creating a junction with distinct electrical characteristics.

In some embodiments, the first doped region 412A and the second doped region 412B can be directly connected to each other, forming a continuous path for electrical current, which can create a seamless interface between the doped regions with different dopants, i.e., N-type and P-type dopants, enabling efficient charge transfer and ensuring the device operates as intended. Such a direct connection can help minimize resistance and enhance the overall performance of the semiconductor device by providing a clear path for current flow.

In some embodiments, the first doped region 412A is located on a first plane and the second doped region 412B is located on a second plane. The first doped region 412A is connected to the BSCA 418A on the first plane. This connection provides the semiconductor device with a reliable and low-resistance path to the BSCA 418A. The BSCA 418A can provide electrical connectivity to external circuits and ground the semiconductor device. By connecting the first doped region 412A to the BSCA 418A, the semiconductor device can effectively manage the current flow, ensuring optimal performance.

In some embodiments, the second doped region 421B can be connected to the BSCA 418B of the semiconductor device on the second plane. By establishing a connection between the second doped region 412B and the BSCA 418B, the semiconductor device is provided with a stable and efficient pathway for electrical signals.

Together, the first doped region 412A and the second doped region 412B and their connections to the BSCA 418A and BSCA 418B ensure that the semiconductor device operates efficiently, with well-defined pathways for current flow and precise control over its electronic properties.

Referring to FIG. 4C now, a semiconductor device with a third doped region between the first doped region and the second doped region is illustrated, in accordance with some embodiments. In some embodiments, the semiconductor device includes STI 410, a first doped region 462A, a second doped region 462B, a third doped region, 462C, a first backside contact, BSCA 468A, a second backside contact, BSCA 468B, an interlayer dielectric, ILD 420, a bottom ILD, BILD 422, back end of line, BEOL 440, a bonding oxide 442, and a carrier wafer 444. In some embodiments, the first doped region 462A, the second doped region 462B and the third doped region 462C are coplanar and located adjacent to each other. This arrangement causes that all three regions lie on the same plane of the semiconductor device, ensuring uniformity in the fabrication process and facilitating control over their interactions. Being adjacent can allow for efficient charge carrier movement between the doped regions.

The third doped region 462C can be a well or a region that has been doped with an inert dopant. An inert dopant is one that does not significantly alter the electrical properties of the semiconductor material but can serve other purposes such as structural reinforcement or isolation. The third doped region 462C can serve as an intermediary layer within the semiconductor device, providing physical and electrical separation between other functional regions, e.g., the first doped region 462A and the second doped region 462B. By placing the third doped region 462C between the first doped region 462A and the second doped region 462B, a barrier that prevents electrical interference and crosstalk between them is formed. Such an isolation can ensure that the electrical characteristics of the first doped region 462A and the second doped region 462B remain distinct and unaffected by each other.

The first doped region 462A can be directly connected to the BSCA 468A to establish an electrical pathway from the first doped region 462A to the external circuitry. This connection can ensure that the first doped region 462A can carry and manage electrical signals and currents as required by the device's operation, maintaining low resistance and high conductivity.

The second doped region 462B can be connected to the BSCA 468B. Similar to the first doped region's connection, this provides a dedicated pathway for electrical signals and currents from the second doped region 462B to the external circuitry. The presence of the BSCA 468B can ensure that the second doped region 462B can operate independently of the first doped region 462A, maintaining its own electrical characteristics and performance parameters without interference.

The first doped region 462A, the second doped region 462B, and the third doped region 462C can all be coplanar and adjacent to each other. Being coplanar means that these regions lie on the same horizontal plane within the semiconductor substrate, which facilitates a streamlined and uniform fabrication process. Such an adjacency ensures that the doped regions are positioned next to each other without overlapping, maintaining the necessary separation provided by the third doped region 462C while enabling efficient layout and integration within the semiconductor device. FIGS. 4D-4E illustrate top views of the FIGS. 4A-4C.

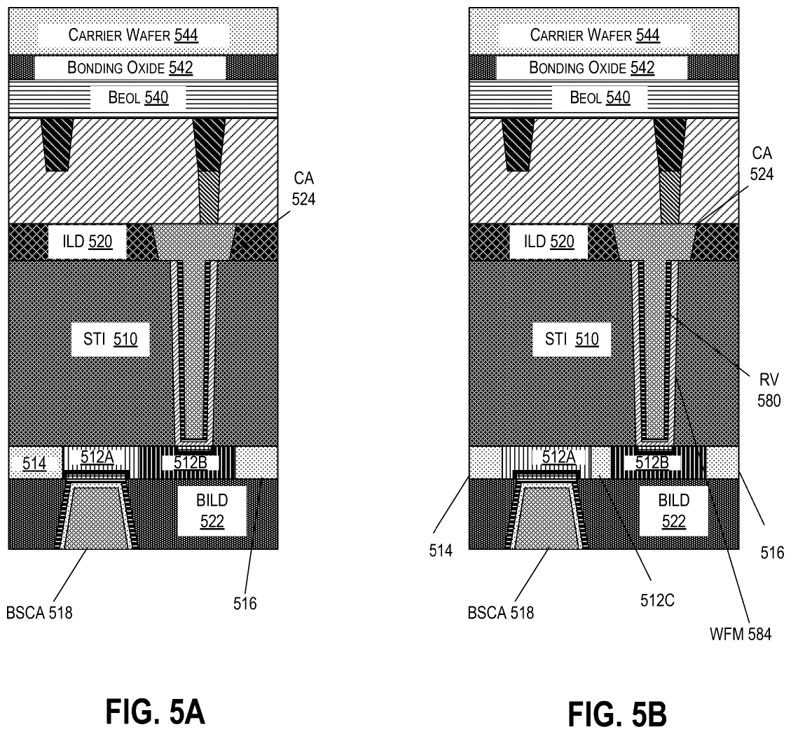

Reference is now made to FIGS. 5A-5B, in which a semiconductor device with a doped region connected to a frontside contact illustrated, according to some embodiments. As illustrated in FIG. 5A, in some embodiments, the semiconductor device includes STI 510, a first doped region 512A, a second doped region 512B, an N-well region 514, a P-well region 516, a backside contact, BSCA 518, an interlayer dielectric, ILD 520, a bottom ILD, BILD 522, a frontside contact, CA 524, back end of line, BEOL 540, a bonding oxide 542, and a carrier wafer 544.

Referring now to FIG. 5A, the first doped region 512A and the second doped region 512B can be designed to be coplanar, meaning they are positioned on the same horizontal plane within the semiconductor substrate. This coplanar arrangement can ensure that both regions are fabricated at the same level, which can simplify the manufacturing process and enhance the structural integrity of the device. By maintaining a coplanar configuration, the two doped regions can interact efficiently and predictably, which is helpful in achieving optimal electrical performance. Additionally, the first doped region 512A and the second doped region 512B can be directly connected to each other. The direct connection can form a seamless electrical pathway between the two regions, allowing for efficient charge carrier movement. The absence of any intermediary layers or barriers between the first doped region 512A and the second doped region 512B can ensure minimal resistance and maximal conductivity, facilitating the high-speed operation of the semiconductor device. This direct connection can also help in maintaining a consistent potential across the regions, further enhancing the device's reliability and performance.

The second doped region 512B can be connected to the CA 524 of the semiconductor device. The CA 524 can serve as an interface for external electrical connections on the top surface of the semiconductor wafer to ensure that the second doped region 512B can easily communicate with external circuits, providing a reliable pathway for electrical signals to enter or exit the semiconductor device.

The integration of the second doped region 512B with the CA 524 can enable the second doped region 512B to play its designated role in the device's operation. By ensuring a robust and efficient connection to the CA 524, the semiconductor device can achieve the desired electrical characteristics and maintain high performance in various applications. The strategic placement and connection of the first doped region 512A and the second doped region 512B, along with their interfaces to the BSCA 518 and the CA 524 can facilitate operation of the semiconductor device.

FIG. 5B illustrates a semiconductor device with a third doped region, in accordance with some embodiments. In some embodiments, the semiconductor device includes STI 510, a first doped region 512A, a second doped region 512B, a third doped region 512C, an N-well region 514, a P-well region 516, a backside contact, BSCA 518, an interlayer dielectric, ILD 520, a bottom ILD, BILD 522, a frontside contact, CA 524, back end of line, BEOL 540, a bonding oxide 542, and a carrier wafer 544.

The third doped region 512C can be either a well or a region that is doped with an inert dopant. The inert dopant can be specifically chosen because it does not significantly alter the electrical properties of the semiconductor material, but it does serve to physically and electrically separate other functional regions within the semiconductor device. The third doped region 512C can act as a barrier that ensures effective isolation between the first doped region 512A and the second doped region 512B. This isolation can prevent electrical interference and crosstalk, which can degrade the performance of the semiconductor device. By incorporating the third doped region 512C between the first doped region 512A and the second doped region 512B, the semiconductor device ensures that the first and second doped regions remain electrically distinct from one another. This isolation further allows each doped region to maintain its specific electrical characteristics without being affected by the adjacent region. The second doped region 512B can be connected to CA 524 of the semiconductor device.

The first doped region 512A, the second doped region 512B, and the third doped region 512C can all be coplanar and adjacent to each other, which simplifies the fabrication process and enhances the structural integrity of the device. The adjacency further ensures that the doped regions are positioned next to each other without any overlapping, maintaining the necessary separation provided by the third doped region.

In some embodiments, the first doped region 512A is directly connected to a frontside via, RV 580, of the semiconductor device to form an ohmic contact. The RV 580 can be a deep via and a portion of the CA 524. The RV 580 can be located within the STI 510 to ensure that the RV 580 is effectively isolated from other components on the semiconductor device, minimizing potential electrical interference and crosstalk. The STI 510, which is filled with insulating material such as silicon dioxide, provides an environment for housing the RV 580, ensuring that the electrical pathways remain distinct and well-insulated.

In some embodiments, the RV 580 can be surrounded by a work function metal, WFM 584. The WFM 584 can be selected based on its ability to provide the desired electrical characteristics, particularly its work function, which influences the barrier heights and the electrical behavior at the metal-semiconductor interface. The presence of the WFM 584 around the RV 580 ensures optimal electrical performance, contributing to low resistance and reliable signal transmission through the RV 580. This metal layer can help maintain the integrity of the electrical connections within the semiconductor device.

Additionally, the ILD 520 can surround the RV 580. The ILD 520 can provide electrical insulation between different layers and components. By enveloping the RV 580 with the ILD 520, the semiconductor device ensures that there is no unwanted electrical interaction between the RV 580 and other parts of the circuitry. The ILD 520 can help to maintain signal integrity, reduce parasitic capacitance, and prevent short circuits, all of which are vital for the proper functioning of the semiconductor device.

Example Act of Fabrication of Semiconductor Device with a Junction Backside Power Delivery Network

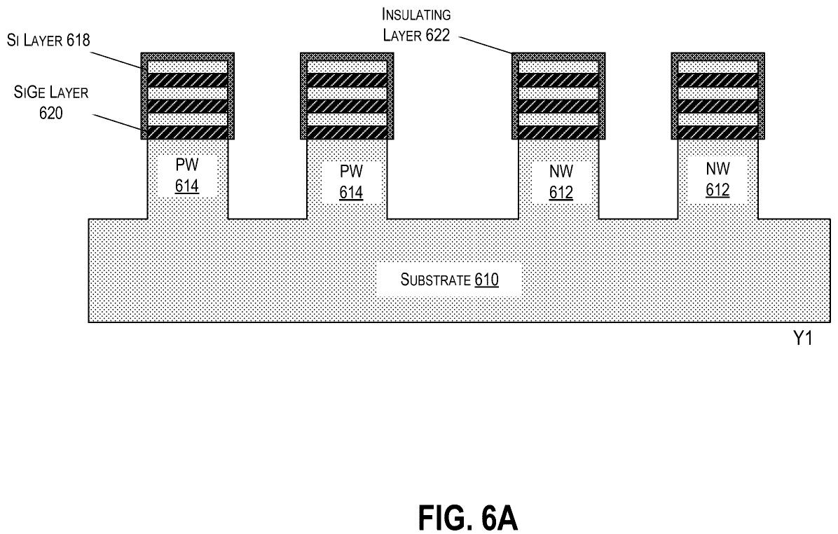

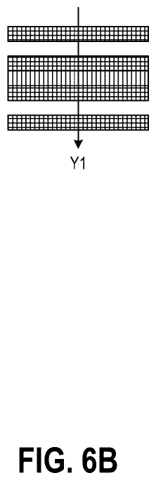

With the foregoing description of an example semiconductor device, it may be helpful to discuss an example process of manufacturing the same. To that end, FIGS. 6-14 illustrate various acts in the manufacture of a semiconductor device, consistent with illustrative embodiments. Figures denoted by A show the acts of fabrication of the semiconductor device and figures denoted by B illustrate top views of the semiconductor device after each act of fabrication of the semiconductor device.

Reference now is made to FIG. 6A, which is a simplified cross-section view of a semiconductor device after etching of the shallow trench isolation, consistent with an illustrative embodiment. In some embodiments, the semiconductor device can include a substrate 610, N-well regions 612, P-well regions 614, silicon layers 616, silicon germanium layers 618, and insulating layer 622.

In the illustrative example depicted in FIG. 6A, the semiconductor device is depicted as being on silicon as the substrate 610, while it will be understood that other types as the substrate 610 can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 610 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

N-well regions 612 and P-well regions 614 can include portions of the substrate 610 that doped with a dopant. The N-well regions 612 can be doped with N-type dopants and the P-well regions 614 can be doped with-type dopants. The silicon layers 616, and silicon germanium layers 618 can be used to form the channel regions. In some embodiments, portions of the substrate 610 are removed, e.g., etched, to form recesses within the semiconductor device. FIG. 6B illustrates a top view of the semiconductor device after etching of the shallow trench isolation.

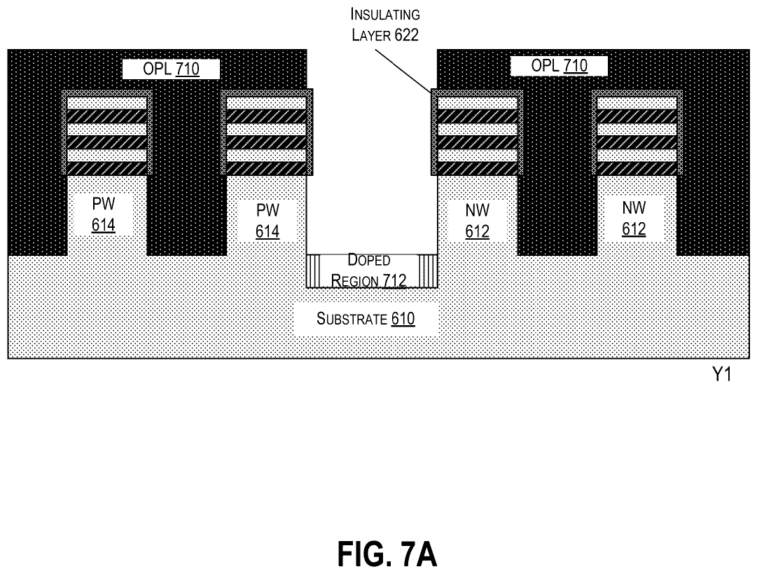

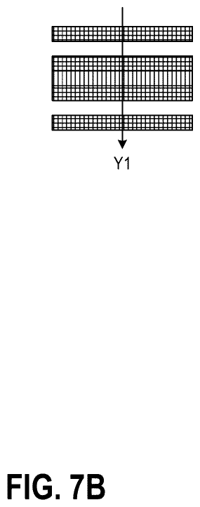

FIG. 7A illustrates a semiconductor device after the implantation of the doped region, in accordance with some embodiments. In some embodiments, an organic planarization layer, OPL 710, is formed over semiconductor device. The OPL 710 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 710 can include any organic polymer and a photoactive compound having a molecular structure that can attach to the molecular structure of the organic polymer. In some embodiments, the OPL 710 material is selected to be compatible with an overlying antireflective coating and/or an overlying photoresist. In some embodiments, the OPL 710 can be applied using spin coating technology, although other techniques are within the contemplated scope of the present disclosure. Subsequently, portions of the OPL 710 that cover a recess are removed and the exposed substrate is doped with a suitable dopant to form the doped region 712. Although a P-type doped region is shown in FIG. 7A, the exposed substrate can be doped with an N-type dopant. Further, in some embodiments, a hard mask can be used to form over the semiconductor device instead of the OPL 710. FIG. 7B illustrates a top view of the semiconductor device after implantation of the doped region.

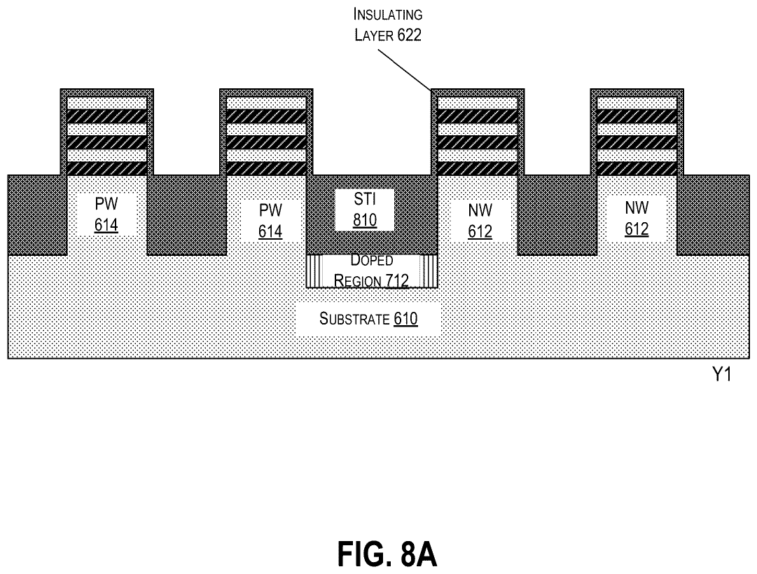

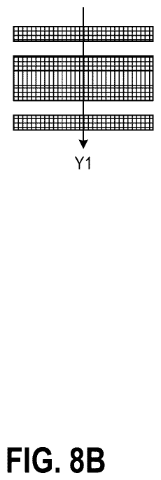

FIG. 8A illustrates a semiconductor device after the formation of the shallow trench isolation, in accordance with some embodiments. In some embodiments, the OPL is removed from the semiconductor device and the recesses can be filled with a suitable material to form the STI 810. The STI 810 can fill the recesses until height of the STI 810 is substantially equal to the height of the N-well regions 612 and the P-well regions 614. FIG. 8B illustrates a top view of the semiconductor device after the formation of the shallow trench isolation.

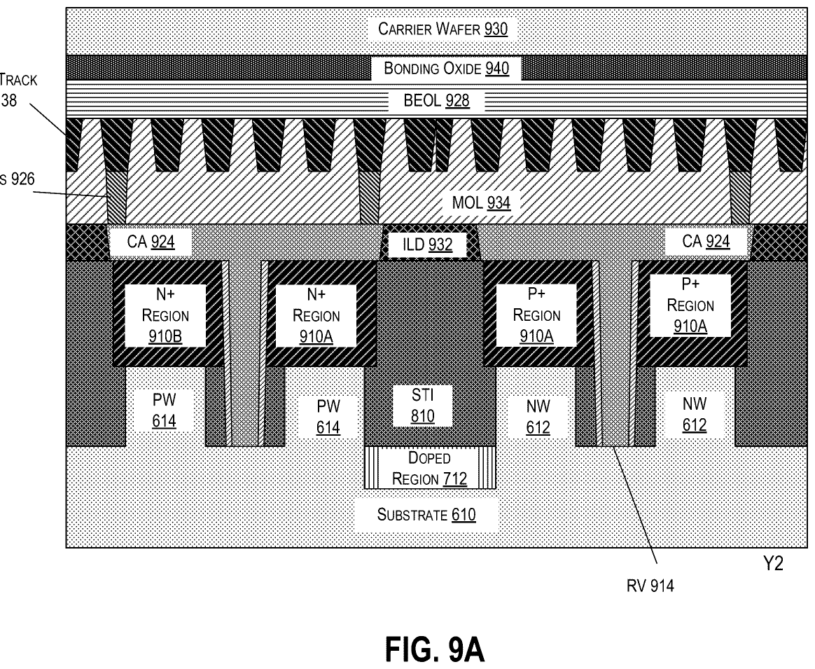

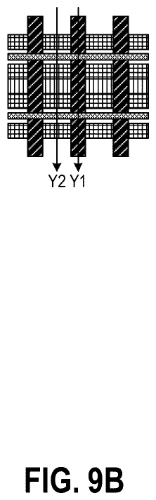

FIG. 9A illustrates active regions of the semiconductor device after the frontside processes, in accordance with some embodiments. In some embodiments, after the frontside processes, the active regions 900A can include P-type doped regions 910A (P+ regions), N-type doped regions 910B (N+ regions), a deep via, RV 914, a frontside contacts, CA 924, a set of vias 926, BEOL 928, a carrier wafer 930, ILD 932, a middle of line, MOL 934, M1 track 938, and a bonding oxide 940.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

The formation of the bonding oxide 940 in semiconductor fabrication involves creating a thin layer of silicon dioxide (SiO₂) on the surface of a silicon wafer. This oxide layer can provide adhesion between different wafers or layers and provides excellent electrical insulation. The silicon wafer surface can be thoroughly cleaned to remove contaminants, organic residues, or native oxides that could interfere with the formation of a uniform bonding oxide. This cleaning process often involves a series of chemical treatments, including the use of solutions such as hydrogen peroxide (H₂O₂), sulfuric acid (H₂SO₄), and hydrofluoric acid (HF), followed by a deionized water rinse. The cleaned silicon wafer is then subjected to a thermal oxidation process to grow the silicon dioxide layer. The wafer is placed in a high-temperature furnace, typically at temperatures ranging from 900° C. to 1100° C. The furnace atmosphere is composed of either dry oxygen (O₂) or a mixture of oxygen and steam (H₂O), depending on whether dry or wet oxidation is desired. In dry oxidation, the silicon reacts with oxygen to form silicon dioxide. In wet oxidation, steam is used to facilitate the oxidation process, resulting in a faster growth rate of the oxide layer. The thickness of the bonding oxide 940 can be controlled by adjusting the oxidation time and temperature. For bonding purposes, the oxide layer can range from a few nanometers to several micrometers in thickness. Thicker oxide layers provide better insulation and mechanical strength, while thinner layers offer lower electrical resistance and better interface properties.

After the oxidation process, the wafer can undergo an annealing step to improve the quality and stability of the silicon dioxide layer. Annealing is performed at high temperatures in an inert atmosphere, such as nitrogen (N₂) or argon (Ar). This step helps to reduce defects in the oxide layer, such as interface traps and fixed charges, and enhances the overall bonding strength between the oxide and the silicon substrate. In some cases, CVD is used to form the bonding oxide 1040 instead of thermal oxidation. In the CVD process, gaseous precursors, such as silane (SiH₄) and oxygen (O₂), react in a controlled environment to deposit a uniform layer of silicon dioxide on the wafer surface.

Before bonding, the oxide surface may undergo additional conditioning to enhance its hydrophilicity and ensure proper adhesion. This step can involve treating the oxide surface with an aqueous solution, such as a mixture of hydrogen peroxide and ammonia (NH₄OH), to create a hydrophilic surface that facilitates strong bonding. Once the bonding oxide layer is formed and conditioned, the wafers can be aligned and bonded together using various techniques, such as direct wafer bonding or adhesive bonding.

A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. FIG. 9B illustrates a top view of the active regions of the semiconductor device after the frontside processes.

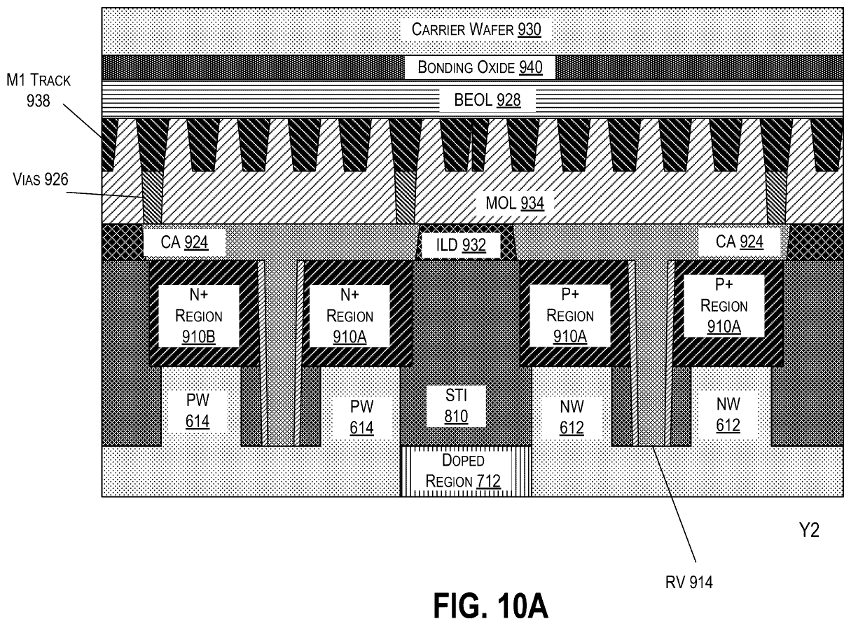

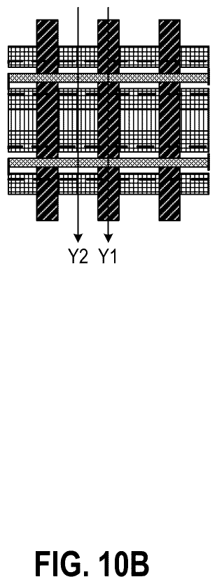

FIG. 10A illustrates the semiconductor device after the recession of the substrate, in accordance with some embodiments. In some embodiments, the substrate is removed from the bottom of the semiconductor device to expose the N-well regions, the P-well regions and the doped region 712. FIG. 10B illustrates a top view of the semiconductor device after the recession of the substrate.

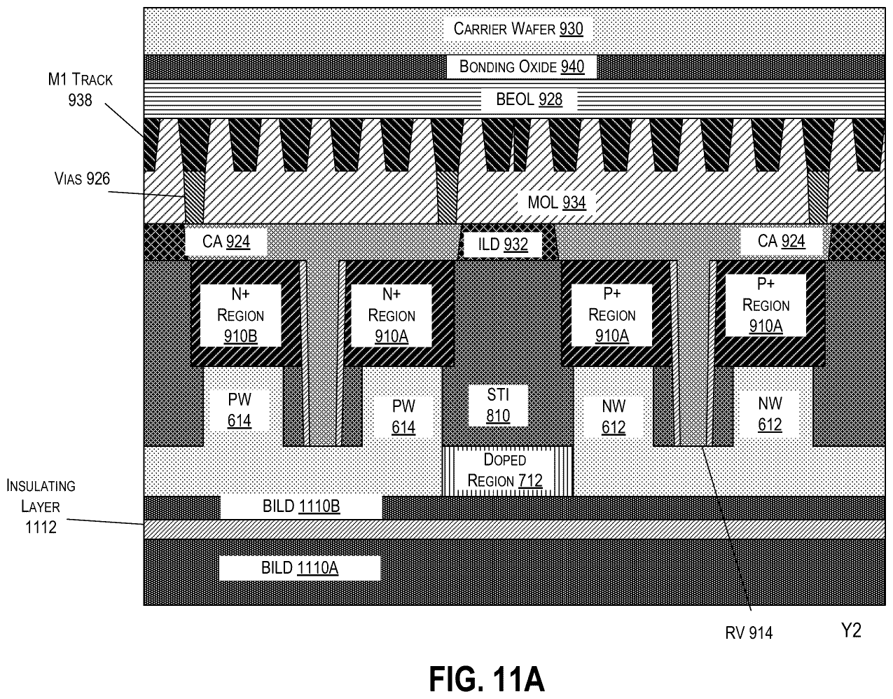

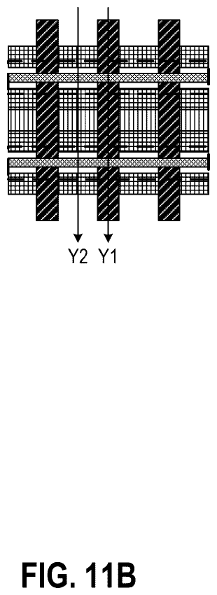

FIG. 11A illustrates the semiconductor device after the deposition of an insulator layer, in accordance with some embodiments. In some embodiments, a first layer of the bottom interlayer dielectric, BILD 1110A is formed over the exposed portions of the N-well regions, the P-well regions and the doped regio. Then an insulating layer 1112 is formed over the BILD 1110A, followed by formation of a second bottom dielectric layer, BILD 1110B. FIG. 11B illustrates a top view of the semiconductor device after the deposition of an insulator layer.

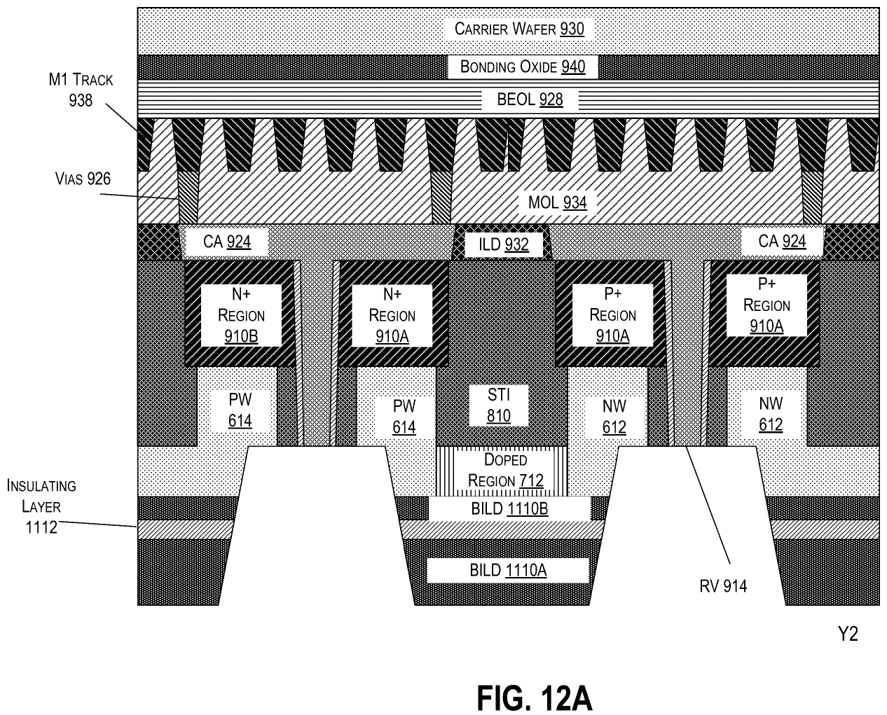

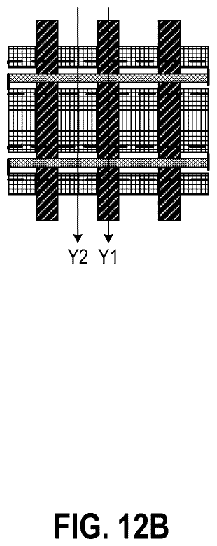

FIG. 12A illustrates the active regions of the semiconductor device after the patterning of the lower via, in accordance with some embodiments. In some embodiments, portions of the BILD 1110A, the insulating layer 1112, and the BILD 1110B, which are located below the RV 914 are removed to expose the RV 914. The patterned portions of the BILD 1110A, the insulating layer 1112, and the BILD 1110B can be used to form the BV. FIG. 12B illustrates a top view of the semiconductor device after the patterning of the lower via.

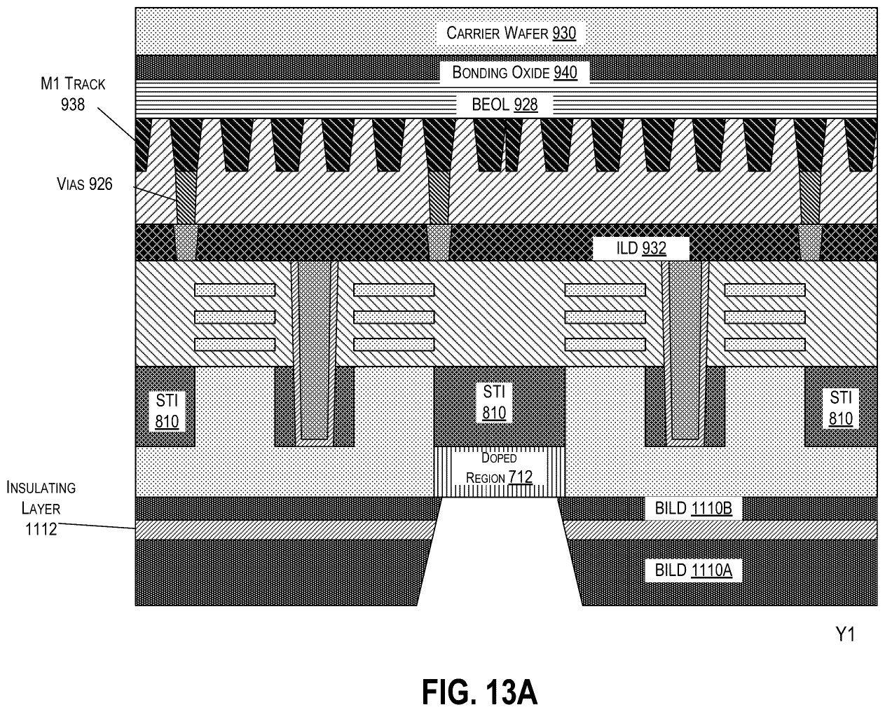

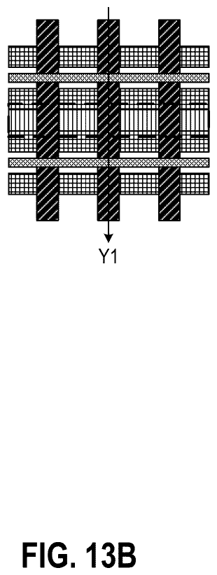

FIG. 13A illustrates the gate regions of the semiconductor device after the patterning of the backside contact, in accordance with some embodiments. In some embodiments, portions of the BILD 1110A, the insulating layer 1112, and the BILD 1110B, which are below the doped region 712 are removed to expose the doped region 712. The patterned portions of the BILD 1110A, the insulating layer 1112, and the BILD 1110B can be used to form the BSCA. FIG. 13B illustrates a top view of the semiconductor device after the patterning of the backside contact.

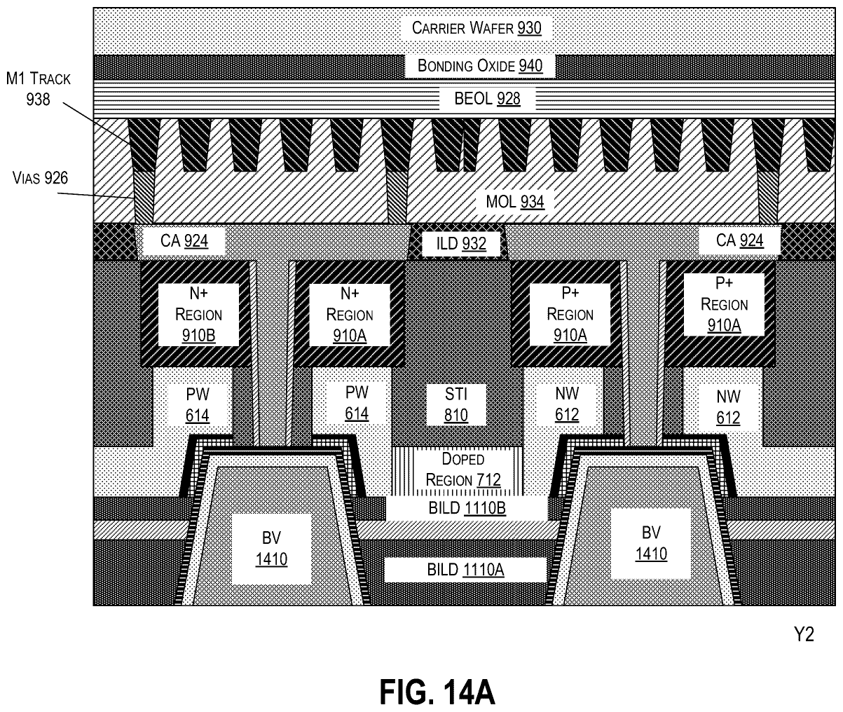

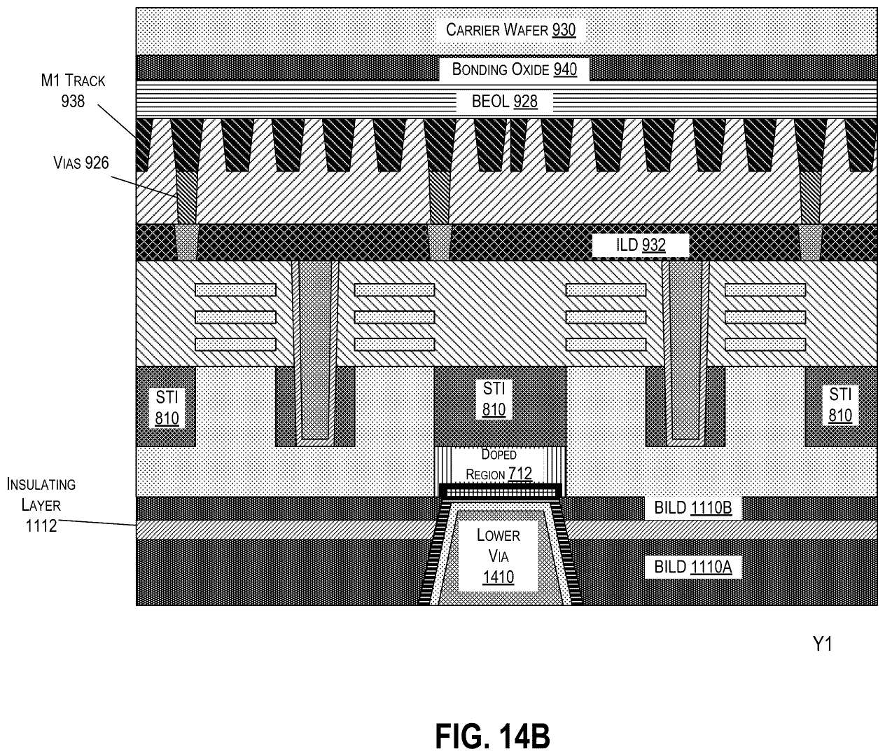

FIG. 14A illustrates the active regions of the semiconductor device after the formation of the lower via, in accordance with some embodiments. In some embodiments, the recesses that are formed after removing portions of the BILD 1110A, the insulating layer 1112, and the BILD 1110B, which are below the doped region 712 are filled with suitable materials to form the BV 1410.

FIG. 14B illustrates the gate regions of the semiconductor device after the formation of the backside contact, in accordance with some embodiments. In some embodiments, the recesses that are formed after removing portions of the BILD 1110A, the insulating layer 1112, and the BILD 1110B, which are below the doped region 712 are filled with suitable materials to form the BV 1410.

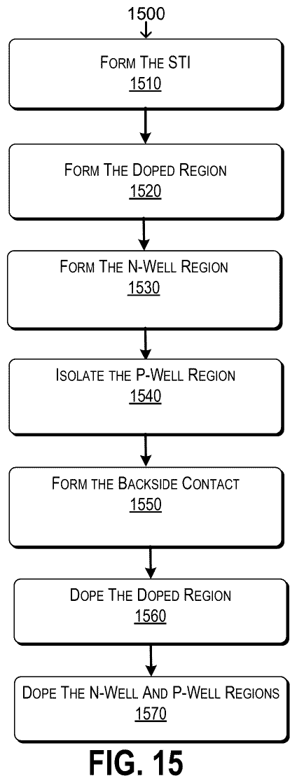

FIG. 15 illustrates a block diagram of a method 1500 for forming the semiconductor device, in accordance with some embodiments. As shown by block 1510, STI is formed. As shown by block 1520, the doped region is formed.

As shown by block 1530, the N-well region is formed. The N-well region is connected to the doped region and the STI on a first side.

As shown by block 1540, the P-well region is formed. The P-well region is connected to the doped region and the STI on the second side.

As shown by block 1550, backside contact is formed.

As shown by block 1560, doped region is doped with a first dopant.

As shown by block 1570, the N-well region and the P-well region are doped with an N-type dopant and a P-type dopant, respectively. The first concentration is higher than the second concentration and the third concentration.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims. It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a shallow trench isolation (STI);
a first doped region under the STI;
an N-well region connected to the first doped region and the STI on a first side first doped region;
a P-well region connected to the first doped region and the STI on a second side of the first doped region; and
a backside contact,
wherein a dopant concentration of the first doped region is higher than the dopant concentration of the N-well region and the dopant concentration of the P-well region.

2. The semiconductor device of claim 1, wherein the first doped region is doped with an N-type dopant or a P-type dopant.

3. The semiconductor device of claim 2, wherein the first doped region is in direct contact with the backside contact to form an ohmic contact across an active region of the semiconductor device and a Schottky contact across a gate region of the semiconductor device.

4. The semiconductor device of claim 3, wherein:
the Schottky contact is configured to control a turn on voltage of the semiconductor device, and
the first doped region in the ohmic contact is connected to one of the P-well region or the N-well region.

5. The semiconductor device of claim 3, wherein the first doped region is surrounded by one of: a first N-well region and a second N-well region, a first P-well region and a second P-well region, or the first N-well region and the first P-well region.

6. The semiconductor device of claim 1, further comprising a second doped region, wherein:
the first doped region or the second doped region is doped with an N-type dopant, and
the first doped region or the second doped region is doped with a P-type dopant.

7. The semiconductor device of claim 6, wherein:
the first doped region is located on a first plane, and
the second doped region is located on a second plane.

8. The semiconductor device of claim 7, further comprising a second backside contact located on the second plane, wherein:
the backside contact is located on the first plane,
the first doped region is connected to the backside contact, and
the second doped region is connected to the second backside contact.

9. The semiconductor device of claim 6, further comprising:
a second backside contact, and
a third doped region, wherein:
the third doped region is a well or a region doped with an inert dopant,
the third doped region isolates the first doped region and the second doped region,
the first doped region is connected to the backside contact,
the second doped region is connected to the second backside contact, and
the first doped region, the second doped region, and the third doped region are coplanar and adjacent to each other.

10. The semiconductor device of claim 6, wherein:
the first doped region and the second doped region are coplanar and directly connected to each other, and
the second doped region is connected to a frontside contact of the semiconductor device.

11. The semiconductor device of claim 6, further comprising a third doped region, wherein:
the third doped region is a well or a region doped with an inert dopant,
the third doped region isolates the first doped region and the second doped region,
the second doped region is connected to a frontside contact of the semiconductor device, and
the first doped region, the second doped region, and the third doped region are coplanar and adjacent to each other.

12. The semiconductor device of claim 6, wherein the first doped region is directly connected to a frontside via of the semiconductor device to form an ohmic contact.

13. The semiconductor device of claim 12, wherein:
the frontside via is located within the STI, and
the frontside via is surrounded by a work function metal (WFM) and an interlayer dielectric (ILD) of the semiconductor device.

14. A method for fabrication of a semiconductor device, the method comprising:
forming a shallow trench isolation (STI);
forming a first doped region under the STI;
forming an N-well region connected to the first doped region and the STI on a first side;
forming a P-well region connected to the first doped region and the STI on a second side;
forming a backside contact;
doping the first doped region with a first dopant and with a first concentration,
doping the N-well region with an N-type dopant and with a second concentration; and
doping the P-well region with a P-type dopant and with a third concentration, wherein the first concentration is higher than the second concentration and the third concentration.

15. The method of claim 14, further comprising surrounding the first doped region by one of: a first N-well region and a second N-well region, a first P-region and a second P-region, and the first N-well region and the P-well region.

16. The method of claim 14, further comprising:
establishing a direct connect between the first doped region and the backside contact;
forming an ohmic contact across an active region of the semiconductor device; and
forming a Schottky contact across a gate region of the semiconductor device.

17. The method of claim 16, further comprising:
providing the Schottky contact to control a turn on voltage of the semiconductor device, and
establishing a direct contact between the first doped region in the ohmic contact and one of the P-well region or the N-well region.

18. The method of claim 14, wherein the first doped region is formed on a first plane, and a second doped region is formed on a second plane, the method further comprising:
forming a second backside contact over the second plane;
forming the backside contact over the first plane;
establishing a connection between the first doped region and the backside contact; and
establishing a connection between the second doped region and the second backside contact.

19. The method of claim 14, further comprising:
forming a second backside contact; and
forming a third doped region, comprising:
isolating the first doped region and a second doped region by the third doped region;
establishing a connection between the first doped region and the backside contact; and
establishing a connection between the second doped region and the second backside contact, wherein:
the third doped region is a well or a region doped with an inert dopant, and
the first doped region, the second doped region, and the third doped region are coplanar and adjacent to each other.

20. A semiconductor device, comprising:
a shallow trench isolation (STI);
a doped region under the STI;
a backside contact below the doped region, wherein:
a dopant concentration of the doped region is higher than the dopant concentration of doped regions connected to the doped region, and
an ohmic contact is formed across an active region of the semiconductor device and a Schottky contact is formed across a gate region of the semiconductor device.
